(19) United States
(12) Patent Application Publication
(10) Pub. No.: US 2018/0083008 A1
(43) Pub. Date: Mar. 22, 2018

(54) MULTI-TIME PROGRAMMABLE (MTP) MEMORY CELLS, INTEGRATED CIRCUITS INCLUDING THE SAME, AND METHODS FOR FABRICATING THE SAME

(71) Applicant: Globalfoundries Singapore Pte. Ltd., Singapore (SG)

(72) Inventors: Pengfei Guo, Singapore (SG); Shyue Seng Tan, Singapore (SG); Kiok Boone Elgin Quek, Singapore (SG)

(21) Appl. No.: 15/267,664

(22) Filed: Sep. 16, 2016

(51) Int. Cl. H01L 27/105; H01L 27/092; H01L 29/78; H01L 29/08; H01L 21/8238; H01L 49/02; H01L 27/06; H01L 29/66

(52) U.S. Cl. CPC H01L 27/1052; H01L 27/0928; H01L 29/7816; H01L 29/0847; H01L 29/66681; H01L 21/823892; H01L 28/40; H01L 27/0629; H01L 29/7833

(57) ABSTRACT

Multi-time programmable (MTP) memory cells, integrated circuits including MTP memory cells, and methods for fabricating MTP memory cells are provided. In an embodiment, an MTP memory cell includes a semiconductor substrate including a CMOS device region and a DMOS device region. The MTP memory cell further includes a high voltage (HV) p-well in the CMOS device region and in the DMOS device region of the semiconductor substrate. An n-channel transistor is disposed over the HV p-well in the CMOS device region and includes a transistor gate. Also, the MTP memory cell includes an n-well overlying the HV p-well in the DMOS region of the semiconductor substrate. An n-channel capacitor is disposed over the n-well and includes a capacitor gate. The capacitor gate is coupled to the transistor gate.

### TECHNICAL FIELD

The technical field generally relates to multi-time programmable (MTP) memory cells, and more particularly relates to MTP cells having reduced cell size as compared to conventional MTP cells.

### BACKGROUND

Multi-time programmable (MTP) memory cells have been recently introduced for beneficial use in a number of applications where customization is required for both digital and analog designs. These applications include data encryption, reference trimming, manufacturing identification (ID), security ID, and many other applications. Incorporating MTP memory cells nonetheless also typically comes at the expense of some additional processing.

For example, some of the existing approaches to constructing MTP memories require additional masking processes to achieve sufficiently high junction breakdown voltage (BV). Also, some of the existing approaches result in MTP memories having large cell sizes due to design rule requirements. In order to achieve smaller cell sizes using existing approaches, multiple un-proven sub-design rule techniques have to be applied.

Accordingly, it is desirable to provide a simple and MTP structure that can be created with no added costs with the standard complementary metal oxide semiconductor (CMOS) structure. Further, it is desirable to provide a method for fabricating an improved MTP memory cell. Furthermore, other desirable features and characteristics will become apparent from the subsequent detailed description and the appended claims, taken in conjunction with the accompanying drawings and this background.

### BRIEF SUMMARY

Multi-time programmable (MTP) memory cells, integrated circuits including MTP memory cells, and methods for fabricating MTP memory cells are provided. In an exemplary embodiment, an MTP memory cell includes a semiconductor substrate including a CMOS device region and a DMOS device region. The MTP memory cell further includes a high voltage (HV) p-well in the CMOS device region and in the DMOS device region of the semiconductor substrate. An n-channel transistor is disposed over the HV p-well in the CMOS device region and includes a transistor gate. Also, the MTP memory cell includes an n-well overlying the HV p-well in the DMOS region of the semiconductor substrate. An n-channel capacitor is disposed over the n-well and includes a capacitor gate. The capacitor gate is coupled to the transistor gate.

In another exemplary embodiment, an integrated circuit device is provided. The integrated circuit device includes a semiconductor substrate and a multi-time programmable (MTP) memory cell formed in and/or over the semiconductor substrate. The MTP memory cell includes a high voltage (HV) well of a first dopant type formed in the semiconductor substrate and a transistor disposed over the HV well and including a transistor gate. Further, the MTP memory cell includes a high voltage (HV) double-diffused region of a second dopant type formed in the HV well and a device disposed over the HV double-diffused region and including a device gate. The transistor gate is coupled to the device gate.

In yet another exemplary embodiment, a method for fabricating a multi-time programmable (MTP) memory cell is provided. The method includes providing a semiconductor substrate having a first region and a second region. The method further includes forming a high voltage (HV) p-well in the first region and in the second region of the semiconductor substrate. Also, the method includes forming a high voltage (HV) n-doped double-diffused region in the HV p-well in the second region. The method also includes forming a transistor over the HV p-well and including a transistor gate and forming a capacitor over the HV n-doped double-diffused region and including a capacitor gate. The method includes coupling the capacitor gate to the transistor gate.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

The various embodiments will hereinafter be described in conjunction with the following drawing figures, wherein like numerals denote like elements, and wherein:

FIG. 1 is a schematic diagram of an MTP memory cell in accordance with an embodiment herein;

FIG. 2 is a top view of an embodiment of an MTP memory cell having the components of FIG. 1 and arranged in accordance with an embodiment herein;

FIG. 3 is a cross section view of an MTP memory cell having the components of FIG. 2;

FIG. 4 is a top view of an embodiment of an MTP memory cell having the components of FIG. 1 and arranged in accordance with another embodiment herein; and

FIG. 5 is a cross section view of an MTP memory cell having the components of FIG. 4.

### DETAILED DESCRIPTION

The following detailed description is merely exemplary in nature and is not intended to limit the MTP memory cells, integrated circuits including MTP memory cells, or methods for fabricating MTP memory cells. Furthermore, there is no intention to be bound by any expressed or implied theory presented in the preceding technical field, background or brief summary, or in the following detailed description.

For the sake of brevity, conventional techniques related to conventional device fabrication may not be described in detail herein. Moreover, the various tasks and processes described herein may be incorporated into a more comprehensive procedure or process having additional functionality not described in detail herein. In particular, various processes in the fabrication of memory cells are well-known and so, in the interest of brevity, many conventional processes will only be mentioned briefly herein or will be omitted entirely without providing the well-known process details. Further, it is noted that memory cells and devices having memory cells include a varying number of components and that single components shown in the illustrations may be representative of multiple components.

As used herein, it will be understood that when an element or layer is referred to as being “over” or “under” another element or layer, it may be directly on the other element or layer, or intervening elements or layers may be present. When an element or layer is referred to as being “on” another element or layer, it is directly on and in contact with the other element or layer. Further, spatially relative terms, such as “upper”, “over”, “lower”, “under” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as being “under” other elements or features would then be oriented “above” the other elements or features. Thus, the exemplary term “under” can encompass either an orientation of above or below. The device may be otherwise oriented (rotated 90 degrees or at other orientations) and the spatially relative descriptors used herein may likewise be interpreted accordingly.

As described herein, an exemplary MTP memory cell is formed with a Transistor plus Capacitor (1T+1C) structure and, accordingly, includes a transistor and a capacitor. Other embodiments may include a CMOS device, which may include a transistor, and a DMOS device, which may include a capacitor. An exemplary MTP memory cell includes an n-channel transistor and an n-channel capacitor, through other arrangements are contemplated. In an exemplary embodiment, the transistor includes a floating gate and the capacitor includes a control gate. Further, the MTP memory cell described herein provides for reduced cell size as compared to conventional MTP memory cells, including conventional 1T+1C structures. For example, conventional memory cells may have a cell size of about 14.5 square micrometers (μm²), whereas an exemplary memory cell described herein has a cell size of about 5.25 μm².

Exemplary embodiments provide for a reduced memory cell size without reducing the breakdown voltage (BV) of the memory cell. For example, while a conventional 14.5 μm² 1T+1C memory cell has a breakdown voltage of about 10.5 volts (V), an exemplary 5.25 μm² 1T+1C memory cell described herein has a breakdown voltage of about 17.5 V.

The process for forming the described MTP memory cell adds no additional masks to an existing process flow for forming integrated circuits. As described herein, an exemplary MTP memory cell is formed with the transistor over a high voltage (HV) doped well. Generally, HV wells are formed with a higher implant energy, hence have larger junction depths as compared to MV or LV wells. Also, the dopant concentration of HV wells is generally lighter than MV or LV wells. For example, an implant energy of a HV well can be about 1 to about 2 MeV, while an implant energy for a MV or LV well is less than 1 MeV. The dopant concentration of an HV well can be about 1E16 to about 1E17 atoms/cm³ and the dopant concentration of a MV/LV well can be about 1E17 to about 1E18 atoms/cm³. Locating the transistor over an HV doped well facilitates operation with the high junction breakdown voltage noted above in comparison with conventional structures.

Embodiments herein generally relate to semiconductor devices. More particularly, some embodiments relate to memory cells, such as non-volatile memory (NVM) devices. Such memory cells, for example, can be incorporated into standalone memory cells, such as USB or other types of portable storage units, or integrated circuits, such as microcontrollers or system on chips (SoCs). The devices or integrated circuits can be incorporated into or used with, for example, consumer electronic products or relate to other types of devices.

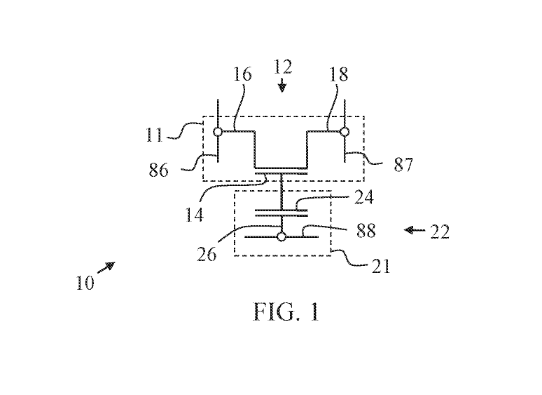

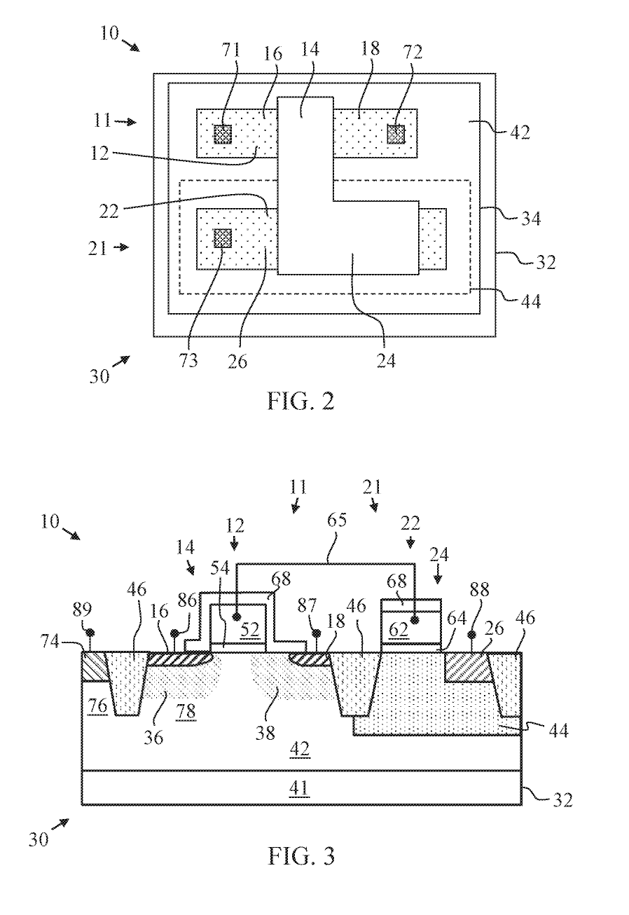

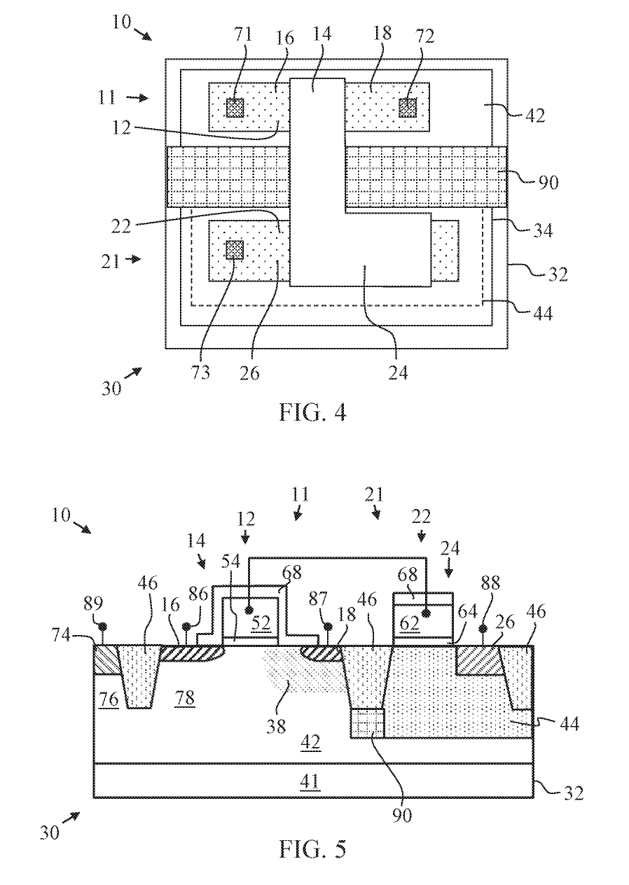

FIG. 1 is a schematic diagram of an embodiment of an MTP memory cell. FIG. 2 provides a top view of an embodiment of an MTP memory cell. FIG. 3 provides a cross section view of an embodiment similar to that of FIG. 2. FIG. 4 provides a top view of another embodiment of an MTP memory cell. FIG. 5 provides a cross section view of an embodiment similar to that of FIG. 4.

As shown in FIG. 1, a memory cell 10 is provided and may encompass a multi-time programmable (MTP) memory cell 10, such as a non-volatile (NV) MTP. As further shown in FIG. 1, memory cell 10 includes a first region 11, such as a CMOS device region 11 including a CMOS device 12, and a second region 21, such as a DMOS device region 21 including a DMOS device 22. In the exemplary embodiment, the CMOS device 12 is a transistor and the DMOS device 22 is a capacitor. In an exemplary embodiment, memory cell 10 includes an n-channel transistor 12 and an n-channel capacitor 22, though the devices may be doped differently.

An exemplary transistor 12 is a metal oxide semiconductor (MOS) transistor. The exemplary transistor 12 includes a gate 14 between first and second diffusion regions 16 and 18, i.e., source and drain regions 16 and 18. An exemplary capacitor 22 is a MOS capacitor. The exemplary capacitor 22 includes a gate 24. A diffusion region 26 is disposed adjacent to the gate 24.

In the exemplary embodiment, the transistor 12 is a storage transistor and the transistor gate 14 may be considered a storage gate. Further, the capacitor 22 may be a control capacitor and the capacitor gate 24 may be considered a control gate.

As illustrated in FIG. 1, the gate 14 and the control gate 24 are commonly coupled. By commonly coupling the gate 14 and the control gate 24, the gate 14 is formed as a floating gate. In one embodiment, such as in FIGS. 2 and 4, a common gate electrode is provided for the floating gate 14 and the control gate 24. Other configurations of the floating and control gates may also be useful.

In the embodiment illustrated in FIG. 1, the first diffusion region 16 of transistor 12 is coupled to a bit line (BL) 86 of the memory cell 10. The second diffusion region 18 of transistor 12 is coupled to a source line (SL) 87 of the memory cell 10. The diffusion region 26 of the control capacitor 22 is coupled to a control gate line (CGL) 88 of the memory cell 10. In one embodiment, the control gate line 88 is disposed along a first direction, such as a word line direction, while the bit line 86 and source line 87 are disposed along a second direction, such as the bit line direction. The first and second directions, for example, are orthogonal to each other. Other configurations of bit line 86, source line 87, and control gate line 88 may also be useful. For example, the source line 87 may be a common source line for memory cells of an array.

FIG. 2 shows a top view of one embodiment of a device 30 including a memory cell 10 as depicted in FIG. 1. FIG. 3 shows a cross sectional view of the device 30 of FIG. 2 (with schematics of metal lines) including memory cell 10. As shown in FIGS. 2 and 3, device 30 is disposed on a semiconductor substrate 32. Herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. The semiconductor substrate 32 may include a compound semiconductor such as silicon carbide, silicon germanide, gallium arsenide, indium arsenide, indium gallium arsenide, indium gallium arsenide phosphide, or indium phosphide and combinations thereof. In an exemplary embodiment, the semiconductor material is a silicon substrate. As referred to herein, a material that includes a recited element/compound includes the recited element/compound in an amount of at least 25 weight percent based on the total weight of the material unless otherwise indicated.

The device 30 may include doped regions having different dopant concentrations formed in the substrate 32. For example, the device 30 may include heavily doped (x+), intermediately doped (x), and lightly doped (x−) regions, where x is the p-type or n-type dopant polarity type. A lightly doped (x−) region may have a dopant concentration of from about 1E11 to about 1E13 atoms/cm³, an intermediately doped (x) region may have a dopant concentration of from about 1E13 to about 1E19 atoms/cm³, and a heavily doped (x+) region may have a dopant concentration of about 1E20 atoms/cm³ or higher. Providing other dopant concentrations for the different types of doped regions may also be useful. For example, the dopant concentration ranges may be varied, depending on the technology node. P-type dopants may include boron (B), aluminum (Al), indium (In) or a combination thereof, while n-type dopants may include phosphorous (P), arsenic (As), antimony (Sb) or a combination thereof.

As shown in FIG. 2, a cell region 34 is provided in the semiconductor substrate 32. The cell region 34, for example, is a cell region in which the memory cell 10 is disposed. Although one cell region 34 is shown, the device 30, as an integrated circuit (IC), may include a plurality of cell regions 34 having multiple memory cells 10 interconnected to form a memory array. Additionally, the semiconductor substrate 32 may include other types of device regions, depending on the types of device or IC. For example, the device 30 may include device regions for high voltage (HV), intermediate or medium voltage (MV) and/or low voltage (LV) devices.

As shown in FIGS. 2 and 3, the cell region 34 includes a deep well 41. An exemplary deep well 41 is n-doped. As further shown, a high voltage (HV) well 42 is located over the deep well 41. For example, an implantation process may be performed to form the HV well 42 over the deep well 41. In an exemplary embodiment, the HV well 42 is p-doped. The cell erase voltage is limited by the junction BV between N+ and p-well at BL. The purpose of the HV well 42 is to improve the junction BV so that a higher voltage can be applied during erase operation. This higher junction BV is attributed to the lighter dopant concentration of the HV well 42 as compared to a MV well in a conventional device.

In FIGS. 2 and 3, the device 30 further includes a high voltage (HV) double-diffused region 44 formed in the HV well 42. In an exemplary embodiment, the HV double-diffused region 44 is formed only in the region of the semiconductor substrate 32 where capacitor 22 will be formed, i.e., not in the region where transistor 12 will be formed. An exemplary HV double-diffused region 44 is n-doped. The maximum voltage for cell program is gated by the junction BV between n-well of the capacitor and surrounding p-well. The dopant concentration of the HV double diffused region 44 (or HVNDDD) is much lower than that of a MV or LV well, which will improve the junction BV at the CGL terminal and allow a higher voltage for program.

The HV double-diffused region 44 may serve as a control well for control gate 24 of control capacitor 22 while the HV well 42 serves as a well for gate 14 of transistor 12. As shown, the HV well 42 and HV double-diffused region 44 are disposed adjacent to each other. The HV well 42 accommodates the transistor 12 and the HV double-diffused region 44 accommodates the control capacitor 22. The HV double-diffused region 44 includes control well dopants and the HV well 42 includes transistor well dopants. The HV double-diffused region 44 may have a light dopant concentration. For example, the dopant concentration of the HV double-diffused region 44 may be from about 1E16 to about 1E18 atoms/cm³. The HV well 42 may be lightly doped with transistor well dopants. For example, the dopant concentration of storage well dopants in the HV well 42 may be from about 1E16 to about 1E17 atoms/cm³. Other control and/or storage well dopant concentrations may also be useful.

The polarity type of the HV double-diffused region 44 depends on the desired polarity type of the control capacitor 22. In the case of control capacitors, control wells are formed with the same polarity as the capacitor type. Herein, the control capacitor 22 is an n-type capacitor. Therefore, the control well dopant is n-type. The polarity type of transistor wells is the opposite of the desired polarity of the transistor. Herein, the transistor 12 is an n-type transistor. Therefore, the storage transistor well dopants are n-type.

A cell isolation region 46, as shown, separates the HV well 42 and the HV double-diffused region 44, as well as the other device regions. The cell isolation region 46 sufficiently isolates the differently doped regions. For example, the cell isolation region 46 provides sufficient overlap to the different wells/regions. The cell isolation region 46 defines the active region in the HV well 42 and the HV double-diffused region 44. For example the cell isolation region 46 defines the active transistor region of the transistor 12 in the HV well 42 and active capacitor region of the capacitor 22 in the HV double-diffused region 44. The cell isolation region 46 is, for example, a shallow trench isolation region. Other types of isolation regions may also be useful.

In FIGS. 2 and 3, transistor 12 is disposed in the transistor active region of the HV well 42. Transistor 12 includes gate 14 between first and second diffusion regions 16 and 18. For example, the gate 14 is formed over the semiconductor substrate 32 and between the first and second diffusion regions 16 and 18 formed in the semiconductor substrate 32.

Exemplary diffusion regions 16 and 18 of transistor 12 are heavily doped regions with first polarity type dopants. The polarity type determines the type of transistor. Herein, the first polarity, i.e., the polarity of first and second diffusion regions 16 and 18, is n-type and the transistor 12 is an n-type transistor.

As shown in FIG. 3, the device 30 may further include lightly doped diffusion (LDD) regions 36 and 38, such as base halo or extension regions. The LDD regions 36 and 38 may be lightly doped with first or second polarity type dopants. In an exemplary embodiment, the LDD regions are lightly doped with the same type dopant as the diffusion regions 16 and 18. In the exemplary embodiment, the LDD regions 36 and 38 are lightly n-doped. The dopant concentrations of the halo and LDD regions are lower than those of the transistor diffusion regions 16 and 18. For example, the dopant concentration of each LDD region 36 and 38 is about 1E18 atoms/cm³. Providing other dopant concentrations for the LDD regions may also be useful. For example, the dopant concentrations may be varied depending on the technology node.

Dielectric spacers (not shown) may be provided on the sidewalls of the gate 14 of transistor 12. The spacers may be used to facilitate forming the LDD regions 36 and 38 and transistor diffusion regions 16 and 18. For example, spacers may be formed after LDD regions 36 and 38 are formed. Spacers may be formed by, for example, forming a spacer layer on the substrate and anisotropically etching it to remove horizontal portions, leaving the spacers on sidewalls of the gates. After forming the spacers, an implant may be performed to form the transistor diffusion regions 16 and 18.

The LDD regions 36 and 38, as described, may be formed by a second implantation process. The second implantation process, for example, may be an implant used to form halo and LDD regions of other devices, such as HV and/or LV devices of the same polarity type. For example, a first LDD implant may be a second implant of other devices elsewhere on the IC, such as MV devices. This enables the same mask used to form regions of other devices to be used to form the LDD regions 36 and 38 of the storage transistor. The use of the same mask enables the device to be formed without the need of extra masks, reducing costs.

As shown in FIG. 3, the gate 14 includes a gate electrode 52 overlying a gate dielectric 54 located on the semiconductor substrate 32. The gate electrode 52, for example, may be a polysilicon gate electrode. The gate dielectric 54, for example, may be an oxide such as a silicon oxide gate dielectric. An exemplary gate dielectric 54 should be sufficient to serve as a storage dielectric for the transistor 12. For example, the gate dielectric 54 should be sufficiently thick to prevent or reduce electron leakage of the transistor 12. Other types of gate electrode or dielectric materials may also be useful.

In FIGS. 2 and 3, control capacitor 22 is disposed in the capacitor active region of the HV double-diffused region 44. The control capacitor 22 includes a control gate 24 disposed over the semiconductor substrate 32 and adjacent the diffusion region 26 within the HV double-diffused region 44.

As shown in FIG. 3, the control gate 24 includes a control gate electrode 62 overlying a control gate dielectric 64 located on the semiconductor substrate 32. The control gate electrode 62, for example, may be a polysilicon control gate electrode. The control gate dielectric 64, for example, may be an oxide such as a silicon oxide control gate dielectric. Other types of gate electrode or dielectric materials may also be useful. The control gate electrode, in one embodiment, is doped with control or capacitor type dopants. For example, the control gate electrode 62 is heavily doped with dopants of the same polarity type dopants as the HV double-diffused region 44.

Capacitor diffusion region 26 is disposed in the semiconductor substrate 32 adjacent to the control gate 24. The capacitor diffusion region 26, in one embodiment, is heavily doped with control or capacitor type dopants. The capacitor diffusion region 26 serves as a contact region to a well capacitor plate while the gate electrode serves as the other (or gate capacitor) plate. In one embodiment, the capacitor gate electrode 62 is doped before forming the capacitor diffusion region 26. For example, a gate electrode layer deposited on the substrate is pre-doped with control dopants and patterned to form the capacitor gate electrode 62. Because the diffusion regions of the capacitor and transistor are doped with dopants of the same polarity, the diffusion regions 16, 18 and 26 may be formed at the same time.

In one embodiment, the transistor gate 14 and capacitor gate 24 are commonly coupled, as indicated schematically by line 65 in FIG. 3. In one embodiment, the transistor gate 14 and capacitor gate 24 form an integral unit, as shown in FIG. 2. For example, the transistor gate 14 and capacitor gate 24 may be formed of the same gate layer or layers. For example, patterning same gate layers create the transistor gate 14 and capacitor gate 24 as a unit. In such cases, the transistor gate 14 and capacitor gate 24 are formed of the same material. For example, the transistor gate electrode and capacitor gate electrode are doped with same type (n-type) dopants. In one embodiment, the transistor gate 14 and capacitor gate 24 are formed from the same gate layer. Other configurations of the gates may also be useful. For example, the gates may be formed from different gate layers.

Metal silicide contacts (not shown) may be provided on contact regions of the memory cell. The metal silicide contacts, for example, may be nickel or nickel-based metal silicide contacts. Other types of metal silicide contacts may also be useful. In one embodiment, metal silicide contacts are provided on the diffusion regions of the transistor and capacitor. A silicide block 68 (shown in FIG. 3) is disposed over the transistor gate 14 and capacitor gate 24. The silicide block 68, for example, is a dielectric material, such as silicon oxide. Other types of silicide blocks may also be useful. The silicide block 68 prevents formation of silicide contacts over the transistor gate 14 and capacitor gate 24. This improves data retention.

In FIG. 3, the first diffusion region 16 is shown to be coupled to bit line 86 of the memory cell 10 through a contact 71, the second diffusion region 18 is coupled to source line 87 of the memory cell 10 through a contact 72, and the control diffusion region 26 is coupled to control gate line 88 of the memory cell 10 through a contact 73.

As further shown in FIG. 3, a diffusion region 74 may be formed in the HV well 42 to provide for electrical connection between the HV well 42 and a well line 89. For this purpose, an exemplary diffusion region 74 may be heavily doped with p-type dopants to interconnect exemplary HV p-well 42 and the well line 89. As shown, the diffusion region 74 is formed in a portion 76 of the HV p-well 42 that is isolated from the portion 78 of the HV p-well 42, where diffusion regions 16 and 18 are formed, by an isolation region 46.

The various lines 86, 87, 88, and 89 of the memory cell 10 may be disposed in metal levels (M) of the device 30. The conductive lines disposed in the same direction may be provided in the same metal level. For example, bit line 86 and source line 87 may be disposed on the same level while control gate line 88 and well line 89 are disposed on a different level. Other configurations of conductive lines and metal levels may also be useful.

As an illustration, the device 30 and memory cell 10 as described in FIGS. 1-3 may be formed by an exemplary semiconductor manufacturing process. In one embodiment, the process of forming device 30 includes providing a semiconductor substrate 32. The semiconductor substrate 32 may be prepared with a deep well 41, such as an n-type deep well 41, and with an HV well 42, such as a p-type HV well 42, overlying the n-type deep well 41, to accommodate other devices, such as I-TV devices, on the semiconductor substrate 32. The semiconductor substrate 32 may be prepared with one or more device or cell regions. A cell region 34 is isolated from another cell region by forming cell isolation regions 46, such as shallow trench isolation (STI) regions. A double-diffused region 44 is formed in the HV well 42 in a device region to accommodate a device, such as a capacitor. For example, an n-doped double-diffused region 44 is formed in the capacitor region, while the HV well 42 remains at the surface of the transistor region.

A gate dielectric layer is deposited on the substrate and across the device regions to form gate dielectric layers of the various devices. For example, a silicon oxide layer is formed on the semiconductor substrate 32 to form gate dielectric layers. The gate dielectric layer is formed with different thicknesses for different device regions. A gate dielectric layer of a MV device, for example, may be thicker than a gate dielectric layer of a LV device. For example, an exemplary gate oxide layer of an MV device may be sufficiently thick to prevent electron leakage. In one embodiment, a gate electrode layer, such as a polysilicon layer, is deposited on the gate dielectric layer and the gate electrode layer and gate dielectric layer are patterned to form gate electrodes 52 and 62 and gate dielectric 54 and 64 of the various devices. In one embodiment, the gate electrode layer is a doped polysilicon layer. For example, a gate electrode layer of a control gate is pre-doped with control or capacitor type dopants to form the control gate. Other gate electrodes may also be suitably doped to form gates of other devices. The gate electrode and gate dielectric layers are patterned to form transistor gates of devices, such as HV, MV and/or LV devices.

As described, HV, MV and/or LV devices may be formed on the same semiconductor substrate 32 over the HV well 42 and HV double-diffused region 44. The process may continue to form a memory cell 10, such as a MTP memory cell. The memory cell 10, in one embodiment, is made of MV device. For example, a transistor 12 of the memory cell is an MV transistor and a capacitor 22 of the memory cell is an MV capacitor.

A dielectric spacer layer may be deposited on the semiconductor substrate 32. The dielectric spacer may be patterned to form gate sidewall spacers. In one embodiment, the exposed substrate regions adjacent to the sidewall spacers are heavily doped with transistor type dopants to form diffusion regions 16 and 18. In one embodiment, diffusion regions 16 and 18 are formed adjacent to the sides of the transistor gate 14 (including the spacers) and diffusion region 26 is formed adjacent to a side of the capacitor gate 24 (including a spacer). A common implant mask may be employed, for example, to form the diffusion regions 16, 18 and 26. N-type dopants may be implanted to form diffusion regions 16, 18 and 26. Further, another implant mask may be employed to form diffusion region 74, where p-type dopants may be implanted. Other techniques may also be used to form the diffusion regions.

The process continues to complete forming the device. The processing may include forming an interlayer dielectric (ILD) layer, contacts to the terminals of the memory cell as well as one or more interconnect levels, final passivation, dicing, assembly and packaging. Other processes to complete forming the device may also be included. Other processes to form the device, as described in FIGS. 1-3 may also be useful.

The embodiment of FIGS. 4 and 5 is similar to the embodiment of FIGS. 2 and 3. Structurally, there are two differences between the two embodiments. First, in FIGS. 4 and 5, the LDD region 36 is not formed in the HV well 42. Rather, the diffusion region 16 shares an interface with the HV well 42. As a result, the embodiment of FIGS. 4 and 5 suppresses punch-through between the N+ diffusion region 16 and the N+ diffusion region 18. Second, an interface well 90 is formed between the HV well 42 and the HV double-diffused region 44. An exemplary interface well 90 is a medium voltage (MV) well. Further, an exemplary interface well 90 is p-doped. The p-doped MV interface well 90 is provided to suppress punch-through between the N+ diffusion region 18 and the HV double-diffused region 44.

During fabrication processing, the interface well 90 may be formed by selectively masking the HV well 42 and performing an implant to form the interface well 90 before formation of the HV double-diffused region 44. Alternatively, the interface well 90 may be formed by selectively masking the HV well 42 and the HV double-diffused region 44 and performing an implant to form the interface well 90 after formation of the HV double-diffused region 44.

In each embodiment, the memory cell described has improved performance while providing reduced cell size as compared to conventional processing. Further, fabrication of the memory cell requires no additional masks, as the memory cell may be formed using a conventional process flow. In the described memory cell, programming may be performed by channel hot hole induced hot electron injection. Further, erase may be performed by FN tunneling to channel. Such a process does not depend on the drain-source breakdown voltage (BVdss).

As described herein, memory cells are provided with improved performance at reduced cell sizes. In each embodiment, a transistor is formed over an HV well of the first dopant type and is coupled to a capacitor formed over an HV double-diffused region of the opposite second dopant type. Through this structural arrangement, memory cell size may be reduced while avoiding performance issues related to breakdown voltage.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration as claimed in any way. Rather, the foregoing detailed description will provide those skilled in the art with a convenient road map for implementing the exemplary embodiment or exemplary embodiments. It should be understood that various changes can be made in the function and arrangement of elements without departing from the scope herein as set forth in the appended claims and the legal equivalents thereof.

1. A multi-time programmable (MTP) memory cell comprising:
a semiconductor substrate including a complementary metal oxide semiconductor (CMOS) device region and a double-diffused metal oxide semiconductor (DMOS) device region;
a high voltage (HV) p-well in the CMOS device region and in the DMOS device region of the semiconductor substrate;
an n-channel transistor disposed over the HV p-well in the CMOS device region and including a transistor gate;
a first diffusion region and a second diffusion region in the CMOS device region;
an n-well overlying the HV p-well in the DMOS region of the semiconductor substrate;
an n-channel capacitor disposed over the n-well in the DMOS region and including a capacitor gate, wherein the capacitor gate is coupled to the transistor gate; and
a capacitor diffusion region in the DMOS region, wherein the n-channel capacitor gate is located between the capacitor diffusion region and the CMOS device region, and wherein the first diffusion region, the second diffusion region, and the capacitor diffusion region are n-doped regions.

2. The MTP memory cell of claim 1 wherein the n-channel transistor includes a first lightly doped diffusion (LDD) region located in the HV p-well and a second lightly doped diffusion (LDD) region located in the HV p-well; and wherein:
the first diffusion region is located in the first LDD region;
the second diffusion region is located in the second LDD region; and
the transistor gate is located between the first diffusion region and the second diffusion region.

3. The MTP memory cell of claim 2 wherein the transistor gate is separated from the second diffusion region by a portion of the second LDD region.

4. The MTP memory cell of claim 1 further comprising an isolation region separating the CMOS device region from the DMOS device region, wherein the n-channel capacitor gate is located between the capacitor diffusion region and the isolation region.

5. The MTP memory cell of claim 1 further comprising an isolation region separating the CMOS device region from the DMOS device region, wherein the n-channel capacitor gate is located immediately adjacent the isolation region.

6. The MTP memory cell of claim 1 wherein the first diffusion region is coupled to a source line, the second diffusion region is coupled to a bit line, and the capacitor diffusion region is coupled to a control gate line.

7. The MTP memory cell of claim 6 further comprising a well contact region formed in the HV p-well, wherein the well contact region is a p-doped region.

8. The MTP memory cell of claim 7 wherein the well contact region is coupled to a well line.

9. The MTP memory cell of claim 1 wherein the HV p-well is separated from the n-well along a bit line current path by a medium voltage (MV) p-well.

10. The MTP memory cell of claim 1 wherein:
the first diffusion region is located in the HV p-well;
the n-channel transistor includes a second lightly doped diffusion (LDD) region located in the HV p-well; and
the second diffusion region is located in the second LDD region; and
the transistor gate is located between the first diffusion region and the second diffusion region.

11. The MTP memory cell of claim 10 wherein the transistor gate is separated from the second diffusion region by a portion of the second LDD region.

12. The MTP memory cell of claim 10 wherein the HV p-well is separated from the n-well along a bit line current path by a medium voltage (MV) p-well.

13. An integrated circuit device comprising:
a semiconductor substrate; and
a multi-time programmable (MTP) memory cell formed in and/or over the semiconductor substrate, wherein the MTP memory cell includes:
a high voltage (HV) well of a first dopant type formed in the semiconductor substrate with a dopant concentration of from about 1E16 to about 1E17 atoms/cm³;
a transistor disposed over the HV well and including a transistor gate;
a high voltage (HV) double-diffused region of a second dopant type formed in the HV well with a dopant concentration of from about 1E16 to about 1E18 atoms/cm³; and
a device disposed over the HV double-diffused region and including a device gate, wherein the transistor gate is coupled to the device gate.

14. The integrated circuit device of claim 13 wherein the HV well is separated from the HV double-diffused region along a bit line current path by a medium voltage (MV) well.

15. The integrated circuit device of claim 13 wherein the transistor includes:
a first diffusion region located in the HV well;
a second lightly doped diffusion (LDD) region located in the HV well; and
a second diffusion region located in the second LDD region, wherein the transistor gate is located between the first diffusion region and the second diffusion region.

16. The integrated circuit device of claim 13 wherein the MTP memory cell includes:
a first diffusion region and a second diffusion region disposed over the HV well and surrounding the transistor gate, wherein the first diffusion region and the second diffusion region are n-doped; and
a device diffusion region disposed over the HV double-diffused region and adjacent the device gate, wherein the device diffusion region is n-doped, and wherein the device gate is located between the transistor and the device diffusion region.

17. The integrated circuit device of claim 13 wherein the MTP memory cell includes:
a first diffusion region and a second diffusion region disposed over the HV well and surrounding the transistor gate, wherein the first diffusion region and the second diffusion region are n-doped;
an isolation region laterally separating the HV double-diffused region from the HV well; and
a device diffusion region disposed over the HV double-diffused region and adjacent the device gate, wherein the device diffusion region is n-doped, and wherein the device gate is located between the device diffusion region and the isolation region.

18. The integrated circuit device of claim 13 wherein the transistor includes:
a first lightly doped diffusion (LDD) region located in the HV well;
a second lightly doped diffusion (LDD) region located in the HV well;
a first diffusion region located in the first LDD region; and
a second diffusion region located in the second LDD region, wherein the transistor gate is located between the first diffusion region and the second diffusion region.

19. The integrated circuit device of claim 18 wherein the high voltage (HV) well has an implant energy of from about 1 to about 2 MeV.

20. A method for fabricating a multi-time programmable (MTP) memory cell, the method comprising:
providing a semiconductor substrate having a first region and a second region;
forming a high voltage (HV) p-well in the first region and in the second region of the semiconductor substrate;
forming a high voltage (HV) n-doped double-diffused region in the HV p-well in the second region;
forming a transistor over the HV p-well and including a transistor gate;
forming a capacitor over the HV n-doped double-diffused region and including a capacitor gate;
forming only one diffusion region in the HV n-doped double-diffused region; and
coupling the capacitor gate to the transistor gate.
